(19) United States
(12) Patent Application Publication
(10) Pub. No.: US 2013/0026496 A1
(43) Pub. Date: Jan. 31, 2013

(54) Semiconductor Device and Manufacturing Method Thereof

(71) Applicants: Huaxiang Yin, Beijing (CN); Qiuxia Xu, Beijing (CN); Dapeng Chen, Beijing (CN)

(72) Inventors: Huaxiang Yin, Beijing (CN); Qiuxia Xu, Beijing (CN); Dapeng Chen, Beijing (CN)

(21) Appl. No.: 13/496,198

(22) PCT Filed: Nov. 28, 2011
(86) PCT No.: PCT/CN2011/001980

§ 371 Date: Mar. 14, 2012

(30) Foreign Application Priority Data
Jul. 29, 2011 (CN) 201110215096.X

(51) Int. Cl. H01L 29/16; H01L 29/788; H01L 21/336

(52) U.S. Cl. 257/77; 438/264; 257/315; 257/E29.3; 257/E29.082; 257/E21.422

(57) ABSTRACT

A method for manufacturing a semiconductor device, comprising forming a tunneling dielectric layer, a storage dielectric layer, a gate dielectric layer and a gate layer sequentially on a semiconductor substrate of a first semiconductor material; patterning the tunneling dielectric layer, the storage dielectric layer, the gate dielectric layer and the gate layer to form a gate stack; forming a groove in the semiconductor substrate on the sides of the gate stack; filling the groove with a second semiconductor material different from the first semiconductor material, meanwhile, the entire device is covered by the dielectric layer. The surface energy level in the channel is made to change by the stress generated by the second semiconductor material and the covering dielectric layer, thereby increasing tunneling current and improving the storage efficiency of the device.

### FIELD OF THE INVENTION

The present invention relates to a semiconductor device and a method for manufacturing the same, in particular to a memory device and a method for manufacturing the same.

### BACKGROUND OF THE INVENTION

Memory devices are used for internal or external storage in electronic elements. Said electronic elements includes, but not limited to, computers, digital cameras, cell phones, MP3 players, personal digital assistants, video game consoles and other devices. There are different types of memory devices, including volatile memories and non-volatile memories. Volatile memory devices, for example, Random Access Memory (RAM), require a stable current to hold their contents. Non-volatile memory devices hold or store information even when power supply to the electronic element is terminated. For example, Read Only Memory (ROM) can hold instructions for operating an electronic device. Electronically Erasable Programmable Read Only Memory (EEPROM) is a kind of non-volatile read only memory, which is erasable by being exposed to electric charges. EEPROM usually includes many memory cells, each having an electrically insulated floating gate to store electric charges transmitted to or removed from the floating gate through programming or erasing operations.

A kind of EEPROM memory cell, such as a flash memory cell, has a floating gate field effect transistor that can hold electric charges. The flash memory cell provides both the speed of volatile memory, such as RAM, and the data holding quality of non-volatile ROM. Advantageously, an array of memory cells can also be electrically erased or re-programmed using a single current pulse rather than electrically erasing or re-programming one cell at one time. A typical memory array includes a large number of memory cells grouped into erasable blocks. Each memory cell can be electrically programmed basis by charging the floating gate and the stored electric charges can be removed from the floating gate through an erasing operation. Thus the data in a memory cell is determined by the presence or absence of the charge in the floating gate.

The flash memory cells under development have higher storage density so as to increase data storage capacity and reduce manufacturing cost. The storage density and data storage capacity of memory cells may be increased by reducing the minimum characteristic size of the cells. However, ever since the sub-40 nm NAND Flash, for example, with the continuous reduction in the characteristic size of the devices, the coupling effect of adjacent memory cells is becoming increasingly serious, so there is a need to continuously increase the P/E (programming/erasing) voltage of the devices to increase efficiency, but as a result, the device reliability and the read signal distribution are reduced, and thus causing a vicious circle.

Therefore, it is desirable to increase the storage density and storage capacity of memory cells while reducing the P/E voltage and increasing the programming efficiency.

### SUMMARY OF THE INVENTION

The object of the present invention is to solve one or more of the above technical problems.

According to one aspect of the present invention, a method for manufacturing a semiconductor device is provided, which comprises:

forming a tunneling dielectric layer, a storage dielectric layer, a gate dielectric layer and a gate layer sequentially on a semiconductor substrate of a first semiconductor material;

patterning the tunneling dielectric layer, the storage dielectric layer, the gate dielectric layer and the gate layer to form a gate stack;

forming a groove in the semiconductor substrate on the sides of the gate stack;

filling the groove with a second semiconductor material different from the first semiconductor material,

wherein the second semiconductor material provides a first stress source, and

the stress source generates a compressive stress and a tensile stress onto the channel according to the shape of the groove and the type of the second semiconductor material,

furthermore, a stress dielectric layer is formed on the semiconductor substrate, which at least covers the second semiconductor material and the gate stack and provides a second stress source.

Wherein, a semiconductor device channel region is formed in the semiconductor substrate, the gate stack is above the channel region, and the stress dielectric layer and the second semiconductor material in the groove generate a uniaxial local strain in the channel region.

Wherein, the uniaxial local strain changes the surface energy level of the channel region, thereby increasing tunneling current.

Wherein, the patterned storage dielectric layer forms a floating gate.

Wherein, the patterned storage dielectric layer forms an electric charge trap layer.

Wherein, the second semiconductor material is SiGe or Si:C.

Wherein, the first semiconductor layer is Si, SOL strained Si, SSOI, SiGe, Ge, III-V, metal oxide semiconductor or polysilicon.

Wherein, the material of the tunneling dielectric layer comprises SiO₂, high-k material and/or a composite layer, and the material of the gate dielectric layer comprises SiO₂, high-k material and/or a composite layer, wherein the high-k material includes HfO₂, SiN and/or Al₂O₃.

Wherein, the material of the storage dielectric layer comprises polysilicon or metal material, and the metal material includes Al, Ta, Ti and/or TiN.

Wherein the material of the storage dielectric layer comprises silicon nitride, nanocrystalline silicon, metal or quantum dots.

The semiconductor device according to the present invention may be a CMOS device.

According to the present invention, the groove is filled with a second semiconductor material that is different from the first semiconductor material, meanwhile, the entire device is covered by a dielectric layer. The surface energy level in the channel is made to change by the stress generated by the second semiconductor material and the covering dielectric layer, thereby increasing the tunneling current and improving the storage efficiency of the device.

According to one aspect of the present invention, a non-volatile memory device on a high pressure strained NMOS channel is provided, and the carrier energy level distribution on the surface layer of the channel is changed by means of the uniaxial local strain process technique, thereby to improve the programming efficiency and reduce the P/E voltage.

According to the present invention, the uniaxial local strain process is used to increase the surface energy level of the channel and to reduce the tunneling potential barrier, thereby increasing the programming current and efficiency without changing the basic storage structure; meanwhile, it helps to hold the storage charge; and the process is simple without any special and additional step and technique.

### BRIEF DESCRIPTION OF THE DRAWINGS

In the figures, the same reference signs represent the same or similar parts, wherein,

FIG. 1 is a sectional view of a semiconductor device according to one embodiment of the present invention during a manufacturing stage;

FIG. 2 is a sectional view of a semiconductor device according to one embodiment of the present invention during a manufacturing stage;

FIG. 3 is a sectional view of a semiconductor device according to one embodiment of the present invention during a manufacturing stage;

FIG. 4 is a sectional view of a semiconductor device according to one embodiment of the present invention during a manufacturing stage;

FIG. 5 is a sectional view of a semiconductor device according to one embodiment of the present invention during a manufacturing stage;

FIG. 6 is a sectional view of a semiconductor device according to one embodiment of the present invention during a manufacturing stage;

FIG. 7 is a sectional view of a manufactured semiconductor device according to one embodiment of the present invention.

### DETAILED DESCRIPTION OF THE PREFERRED EMBODIMENTS

One or more aspects of the embodiment of the present invention will be described below with reference to the figures, wherein throughout the figures, the same elements are usually represented by the same reference signs. In the descriptions below, many specific details are elucidated for the purpose of explanation, so that a thorough understanding of one or more aspects of the embodiment of the present invention can be provided. However, it is obvious to those skilled in the art that one or more aspects of the embodiment of the present invention may be implemented by said specific details of a lower degree.

In addition, although specific features or aspects of the embodiment are disclosed with respect to only one preferred embodiment among some preferred embodiments, such features or aspects can be combined with one or more other features or aspects of other preferred embodiments that might be desirable for and advantageous to any given or specific application.

An exemplary method of manufacturing a semiconductor device according to the embodiment of the present invention first provides a semiconductor substrate 1, as shown in FIG. 1. The material of the semiconductor substrate 1 includes, but not limited to, Si, SOL strained Si, SSOI, SiGe, Ge, III-V, metal oxide semiconductor, polysilicon, and the like. Although the present invention is described using monocrystalline silicon hereinafter, embodiments using other semiconductor materials are also explicitly considered herein.

A tunneling dielectric layer 120 is formed on the upper surface of the semiconductor substrate 1. The tunneling dielectric layer 120 may be made of SiO₂, or high-k materials such as HfO₂, SiNₓ and Al₂O₃, or composite layers.

Then, a storage dielectric layer 130 is formed on the tunneling dielectric layer 120. With respect to a floating gate structure, the material of the storage dielectric layer 130 may be polysilicon or such metal materials as Al, Ta, Ti and TiN; with respect to a charge trap flash (CTF) structure, the material of the storage dielectric layer 130 may be charge trap materials such as silicon nitride, nanocrystalline silicon, metal and quantum dots.

Next, a gate dielectric layer 140 is formed on the storage dielectric layer 130, and the material of the gate dielectric layer 140 may be SiO2, or high-k materials such as HfO2, SiNx and Al2O3, or composite layers.

Then, a gate layer 150 is formed on the gate dielectric layer 140, and the material of the gate layer may be polysilicon or metal.

Afterwards, the tunneling dielectric layer 120, the storage dielectric layer 130, the gate dielectric layer 140 and the gate layer 150 are patterned to form a gate stack. The patterned storage dielectric layer forms a floating gate or a charge trap layer of the memory cell, the patterned gate layer 150 forms the control gate of the memory cell. The gate stack may also include a gate hard mask layer (not shown in the figures), which provide some advantages or uses during processing, such as protecting the layers thereunder from subsequent ion implantation processes. In the embodiments of the present invention, said hard mask layer may be formed using materials conventionally used as hard masks, for example, a conventional dielectric material.

After forming the gate stack, an ion implantation process is performed so as to highly dope portions of the substrate adjacent to the gate stack, and the dopant used has a conduction type opposite to that of the substrate.

According to an alternative example of the present invention, the dopant used in the ion implantation process may be selected based on the capability in increasing the etch rate of the substrate material, and said dopant is implanted into the substrate material. The specific dopant selected for the ion implantation process may be selected according to the material of the substrate and the etchant used in a subsequent etching process. Since most substrates contain a large silicon, germanium or indium antimonide component, dopants that can increase the etch rate of silicon, germanium or indium antimonide are usually selected. In the embodiments of the present invention, the specific dopants that may be selected for increasing the etching rate of the substrate include, but not limited to, carbon, phosphor and arsenic.

According to an alternative example of the present invention, the ion implantation substantially occurs in a vertical direction (i.e. a direction perpendicular to the substrate). In some embodiments, at least a part of the ion implantation may occur in an angled direction, so that ions are implanted below the gate stack. As mentioned above, if the gate stack includes a metal layer, then a dielectric hard mask can be formed to prevent doping the metal layer.

Next, an anneal is performed to further drive the dopants into the substrate and to reduce any damage to the substrate during the ion implantation process. The anneal may be performed at a temperature between 700° C. to 1100° C.

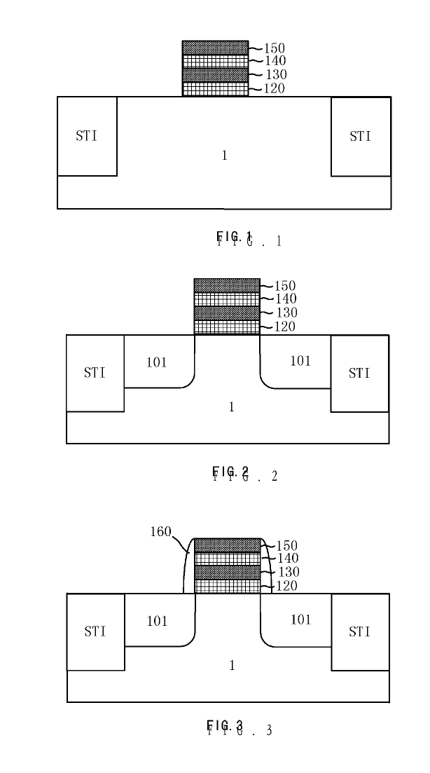

FIG. 2 shows the substrate that has undergone the ion implantation and diffusion process. As shown, the ion implantation process generates two doped regions 101 adjacent to the gate stack. When exposed to a proper etchant, the etch rate of the doped regions 101 will be higher than that of the surrounding substrate material. One of the doped regions 101 will be used as a part of the source region of the memory cell, while the other of the doped regions 101 will be used as a part of the drain region of the memory cell. In each embodiment of the present invention, the size of the doped regions 101, including the depth thereof, may vary according to the requirement of the memory cell to be formed.

Then, as shown in FIG. 3, sidewall spacers 160 are formed on either side of the gate stack. Said sidewall spacers may be formed by conventional materials, including, but not limited to, silicon nitride, silicon oxide or a composite layer of the two. The width of the sidewall spacers may be selected according to design requirements of the device being formed.

Afterwards, an etch process (e.g. dry etch) is performed to etch the doped regions to form grooves 103. The doped regions may be etched partially or completely. According to one embodiment of the present invention, the etched grooves are adjacent to the gate stack and have a depth smaller than that of the doped regions. The dry etch process may use an etchant recipe that is complementary to the dopant used in the ion implantation process so as to increase the etch rate of the doped regions.

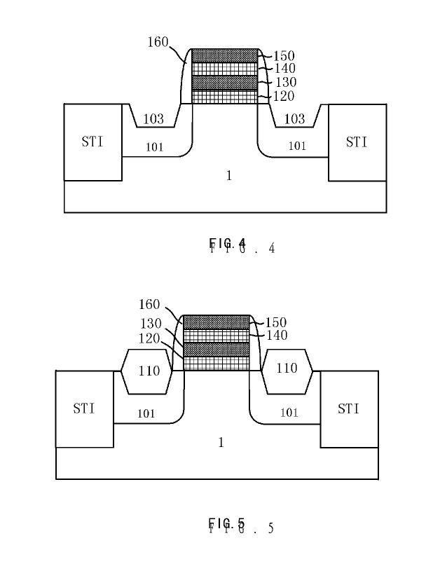

After finishing the dry etch process, a wet etch process may be used to clean and further etch the grooves. The wet etch, on one hand, provides a clean surface on which subsequent processes can be performed, and on the other hand provides a smooth surface on which a high quality epitaxial deposition can occur by removing a part of the substrate along, for example, the <111> and <001> crystal planes. As shown in FIG. 4, the wet etch causes edges of the grooves 103 to follow the <111> and <001> crystal planes.

Formation of the grooves is not limited to the above-mentioned process, but any other processes known in the art can be used.

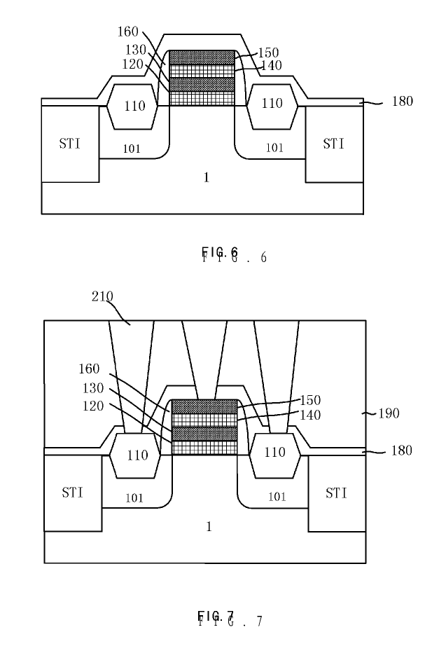

After the etch process, the grooves may be filled with a second semiconductor material (e.g. silicon alloy) by means of a selective epitaxial deposition process, as shown in FIG. 5, thus forming the source and drain regions 110, wherein the surface of the second semiconductor material is flush with or higher than the surface of the substrate. Preferably, when the memory cell is an NMOS transistor, the surface of the second semiconductor material is higher than the surface of the substrate, and the vertical cross section thereof is a rhomb; when the memory cell is a PMOS transistor, the surface of the second semiconductor material is flush with the surface of the substrate, and the vertical cross section thereof is an inversed trapezoid. In some embodiments, the second semiconductor material may be in situ doped silicon germanium, in situ doped silicon carbide or in situ doped silicon. The silicon alloy may be deposited using a CVD process.

In the present invention, the crystal lattice spacing of the silicon alloy material deposited in the grooves is different from that of the substrate material. The difference in crystal lattice spacing causes a tensile stress or a compressive stress in the channel region of the memory cell. As is known to those skilled in the art, deciding whether a tensile stress or a compressive stress is caused depends on whether the conduction type of the channel region of the memory cell is an N type or a P type.

According to the embodiment of the present invention, when the memory cell is an NMOS transistor, the grooves may be filled with Si:C (the atomic number percentage of C may be 0-2%, for example, 0.5%, 1% or 1.5%, and the content of C may be adjusted flexibly according to the need of the process). Si:C provides a tensile stress to the channel region of the memory cell, which helps to improve the performance of the semiconductor device.

According to the embodiment of the present invention, when the memory cell is a PMOS transistor, the grooves may be filled with silicon germanium (SiGe for short). Si1-xGex (the atomic number percentage of Ge may be any value between 10%-70%, specifically, 20%, 30%, 40%, 50% or 60%) can provide a compressive stress to the channel region of the memory cell, which helps to improve the performance of the semiconductor device.

The ion doping operation (i.e. doping in situ) may be directly performed during generating Si:C and SiGe, for example, doping a reactant containing a doping ion component into the reactants for generating Si:C and SiGe; or the ion doping may be performed through an ion implantation process after generating Si:C and SiGe.

Doping in situ may have the following advantages: since the dopant introduced into the second semiconductor material is incorporated into the substituent position of the crystal lattice structure during doping in situ, the need of activating and annealing the dopant is eliminated, thus minimizing the thermal diffusion of the dopant.

SiGe and Si:C can apply a uniaxial stress in the channel region of the memory cell, thus the carrier mobility is increased due to said uniaxial stress. With respect to SiGe, the uniaxial stress may be a compressive stress, thus hole mobility is increased due to the uniaxial compressive stress. With respect to Si:C, the uniaxial stress may be a tensile stress, thus the electron mobility is increased due to the uniaxial tensile stress.

Next, the hard mask layer is removed by etching (if a hard mask layer has been formed previously) to expose the gate layer 150.

According to one embodiment, after removing the hard mask layer, a metal layer (not shown) is deposited and an anneal is carried out to induce the metal layer to react with the semiconductor material thereunder, thereby forming a metal semiconductor alloy on the exposed semiconductor surface. Specifically, source and drain metal semiconductor alloys are formed on the source and drain regions. A gate metal semiconductor alloy is formed on the gate layer (e.g. a polysilicon layer). When the second semiconductor material includes such silicon alloy as silicon germanium alloy or silicon carbon alloy, the source and drain metal semiconductor alloys include such silicide alloy as silicide germanide alloy or silicide carbon alloy. The methods of forming various metal semiconductor alloys are known in the prior art.

Then, as shown in FIG. 6, a stress dielectric layer 180 is formed on the semiconductor substrate, and the material of the stress dielectric layer may be silicon nitride. When the memory cell is an NMOS transistor, a tensile-stressed layer is formed; when the memory cell is a PMOS transistor, a compressive-stressed layer is formed.

Next, an interlayer dielectric layer 190 is formed on the stress dielectric layer, the interlayer dielectric layer may be one or a combination of doped or undoped silicon oxide glass (e.g. fluorosilicate glass, borosilicate glass, phosphorosilicate glass, boron-phosphorosilicate glass, silicon-carbon oxide or silicon carbon oxynitride) and a dielectric material with a low dielectric constant (e.g. black diamond, coral). The interlayer dielectric layer may be formed by Chemical Vapor Deposition (CVD), Pulsed Laser Deposition (PLD), Atomic Layer Deposition (ALD), Plasma Enhanced Atomic Layer Deposition (PEALD) or other appropriate processes.

Various contact holes are formed in the stress dielectric layer and the interlayer dielectric layer and are filled with metal, so that various contact vias 210 are formed. Specifically, the contact vias are formed on the gate metal semiconductor alloy and on the source and drain metal semiconductor alloys. Thus the semiconductor device as shown in FIG. 7 is formed.

In the integrated circuit logic process of the present invention, strain engineering is adopted which can effectively change the effective energy level of carriers on the surface of the channel, thereby influencing the numeric value of the tunneling current of the storage medium and optimizing the memory programming of the device.

The semiconductor device and the manufacturing method thereof according to the present invention adopts strain engineering to increase the compressive energy level of carrier distribution in the channel of substrate, so the height of the tunneling potential barrier is reduced, and the tunneling current used for programming can be greatly increased accordingly, thereby increasing the programming efficiency and reducing the programming voltage; meanwhile, the potential barrier height or the effective thickness of the tunneling dielectric do not have to be reduced, and the numerical value of the inverse leakage current is not increased, thus the storage lifetime of the floating gate charges is expanded.

The present invention is described with reference to the embodiment of a memory cell having a flash memory structure, but those skilled in the art will understand that the present invention can also be applied to other types of memory devices, such as RAM, SRAM (Static Random Access Memory) or DRAM (Dynamic Random Access Memory). Therefore, the present invention should not be limited to the illustrated exemplary embodiments. In addition, the flash memory structure can also be other structures, including but not limited to those shown in this application. Moreover, it shall be noted that the various layers and structures described herein may be formed on the substrate in any sequence, and that the process of manufacturing said structures shall not be limited to the sequence given for describing said structures, said sequence is only selected for convenience.

Furthermore, the scope to which the present invention is applied is not limited to the process, mechanism, manufacture, material composition, means, methods and steps described in the specific embodiments in the specification. Those skilled in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the teaching of the present invention without departing from the protection scope thereof.

The present invention is described with reference to specific preferred embodiments, but other embodiments are also feasible, for example, other types of stress generation materials can also be used, as will be apparent to those skilled in the art. In addition, any step for forming the stressed layer can also be used according to the parameters of the described embodiments, as will be apparent to those skilled in the art. Therefore, the spirit and scope of the appended claims should not be limited to the descriptions of the preferred embodiments given herein.

What is claimed is:

1. A method for manufacturing a semiconductor device, comprising:
forming a tunneling dielectric layer, a storage dielectric layer, a gate dielectric layer and a gate layer sequentially on a semiconductor substrate of a first semiconductor material;
patterning the tunneling dielectric layer, the storage dielectric layer, the gate dielectric layer and the gate layer to form a gate stack;
forming a groove in the semiconductor substrate on the sides of the gate stack;
filling the groove with a second semiconductor material different from the first semiconductor material,
wherein the second semiconductor material provides a first stress source, and the stress source generates a compressive stress and a tensile stress onto the channel region of the semiconductor device according to the shape of the groove and the type of the second semiconductor material.

2. The method according to claim 1, further comprising:
forming a stress dielectric layer on the semiconductor substrate, which at least covers the second semiconductor material and the gate stack and provides a second stress source.

3. The method according to claim 2, wherein the gate stack is above the channel region, and the stress dielectric layer and the second semiconductor material in the groove generate a uniaxial local strain in the channel region.

4. The method according to claim 3, wherein the uniaxial local strain changes the surface energy level of the channel region, thereby increasing tunneling current.

5. The method according to claim 2, wherein the patterned storage dielectric layer forms a floating gate.

6. The method according to claim 2, wherein the patterned storage dielectric layer forms an electric charge trap layer.

7. The method according to claim 2, wherein the second semiconductor material is SiGe or Si:C.

8. The method according to claim 1, wherein when the semiconductor device is a PMOS device, the shape of the vertical cross section of the second semiconductor material is an inversed trapezoid, when the semiconductor device is an NMOS device, the shape of the vertical cross section of the second semiconductor material is a rhomb.

9. The method according to claim 2, wherein the material of the tunneling dielectric layer comprises SiO₂, high-k material and/or a composite layer, and the material of the gate dielectric layer comprises SiO₂, high-k material and/or a composite layer.

10. The method according to claim 5, wherein the material of the storage dielectric layer comprises polysilicon or metal material.

11. The method according to claim 6, wherein the material of the storage dielectric layer comprises silicon nitride, nanocrystalline silicon, metal or quantum dots.

12. A semiconductor device, comprising:
a semiconductor substrate of a first semiconductor material, a gate stack on the semiconductor substrate, the gate stack comprising a tunneling dielectric layer, a storage dielectric layer, a gate dielectric layer and a gate layer which are patterned, a groove in the semiconductor substrate on the sides of the gate stack, which are filled with a second semiconductor material different from the first semiconductor material, wherein the second semiconductor material provides a first stress source, and the stress source generates a compressive stress and a tensile stress onto the channel region of the semiconductor device according to the shape of the groove and the type of the second semiconductor material.

13. The semiconductor device according to claim 12, further comprising:
a stress dielectric layer on the semiconductor substrate, which at least covers the second semiconductor material and the gate stack and provides a second stress source.

14. The semiconductor device according to claim 13, wherein the gate stack is above the channel region, and the stress dielectric layer and the second semiconductor material in the groove generate a uniaxial local strain in the channel region.

15. The semiconductor device according to claim 14, wherein the uniaxial local strain changes the surface energy level of the channel region, thereby increasing tunneling current.

16. The semiconductor device according to claim 13, wherein the patterned storage dielectric layer forms a floating gate.

17. The semiconductor device according to claim 13, wherein the patterned storage dielectric layer forms an electric charge trap layer.

18. The semiconductor device according to claim 13, wherein the second semiconductor material is SiGe or Si:C.

19. The semiconductor device according to claim 12, wherein when the semiconductor device is a PMOS device, the shape of the vertical cross section of the second semiconductor material is an inversed trapezoid, when the semiconductor device is an NMOS device, the shape of the vertical cross section of the second semiconductor material is a rhomb.

20. The semiconductor device according to claim 13, wherein the material of the tunneling dielectric layer comprises SiO₂, high-k material and/or a composite layer, and the material of the gate dielectric layer comprises SiO₂, high-k material and/or a composite layer.

21. The semiconductor device according to claim 16, wherein the material of the storage dielectric layer comprises polysilicon or metal material.

22. The semiconductor device according to claim 17, wherein the material of the storage dielectric layer comprises silicon nitride, nanocrystalline silicon, metal or quantum dots.
